(19) United States
(12) Patent Application Publication
(10) Pub. No.: US 2002/0130033 A1
(43) Pub. Date: Sep. 19, 2002

(54) Process for metal plating liquid crystalline polymers and compositions related thereto

(76) Inventors: Gunter Beitinger, Neumarkt (DE); Gerald Kolbeck, Amberg (DE)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/062,818

(22) Filed: Nov. 13, 2001

Related U.S. Application Data
(62) Division of application No. 09/235,559, filed on Jan. 22, 1999, now abandoned.
(60) Provisional application No. 60/073,194, filed on Jan. 30, 1998.

(51) Int. Cl. C23C 14/32; C23C 14/42

(52) U.S. Cl. 204/192.14; 427/531; 427/524; 427/523; 428/1.1

(57) ABSTRACT

Liquid crystalline polymers (LCP) may be sputter-coated or ion-plated with palladium to yield palladium coated LCP parts. These may be electrolytically plated, as with copper, using normal or unusually high current densities, to make metal plated LCP in which the metal has good adhesion to the LCPs. Before or after the electrolytic plating, the metal coating may be patterned. Parts containing patterned metal surface may be used as circuit boards or printed wire boards.

This application claims the benefit of U.S. Provisional Application No. 60/073,194, filed Jan. 30, 1998.

### FIELD OF THE INVENTION

This invention relates to a novel process for improved adhesion of metal coatings to liquid crystalline polymers by sputter coating or ion plating the polymer with a thin layer of palladium, and compositions thereof.

### BACKGROUND OF THE INVENTION

Polymers of various kinds are plated (coated) with metals for a variety of reasons, often to make the surface electrically conductive, or optically reflective, or merely for a decorative effect. Such compositions are used in a variety of applications, but especially in printed circuits and printed wiring boards. In many of these applications, good adhesion of the metal coating to the polymer is important to the functioning of the metal plated polymer in that application.

Thermotropic liquid crystalline polymers (LCPs) have many properties which make them attractive for use in items such as circuits, among them low coefficient of thermal expansion, good heat resistance, low water absorption, good electrical properties, and in many cases good flammability resistance. However, it is also well-known in the art that LCPs are usually difficult to adhere to other materials, including metals. While many thermoplastics can be satisfactorily metallized by vacuum deposition or by a combination of electroless and electroplating, LCPs metallized in the same manner have very poor adhesion to metal coatings and not good enough for many uses.

Copper is commonly used in the prior art for sputtering onto LCPs and subsequently electrolytically plated with a metal such as with copper. However, the peel strengths of the resulting metal coatings from the LCP are often very low, with the metal sometimes spontaneously delaminating from the polymer. Therefore improved methods of coating LCPs with metals are of continuing practical interest.

U.S. Pat. No. 5,209,819, European Patents 214,827 B1 and 407,129 B1, European Patent Application 402,028, and K. Feldmann, et al., Metalloberflaeche, vol. 51, p. 349-352(1997), describe metal plating LCPs by various methods including sputtering and ion plating. No mention is made of using palladium as the metal, nor of electroplating the sputtered metal layer at relatively high-current densities.

### SUMMARY OF THE INVENTION

The present invention, according to one aspect, relates to a process for coating a thermotropic liquid crystalline polymer with palladium comprising coating said surface with palladium by sputtering or ion plating.

The present invention also provides a composition, comprising, a thermotropic liquid crystalline polymer coated with palladium; wherein said palladium has a thickness of less than about 3 μm, and has an adhesive strength to said liquid crystalline polymer of at least about 2 MPa when measured according to the method of DIN EN 582.

Another aspect of the invention is a process for making a metal coated liquid crystalline polymer composition, comprising electrolytically metal plating a liquid crystalline polymer having a palladium surface layer less than about 3 μm thick; wherein said metal plating takes place on a surface of said palladium layer, and a current density during said metal plating is at least about 5 A/dm² of an area of said surface of said palladium layer, or said metal plating takes place at a rate of at least 1 μm/min, or both.

Additionally, there is provided a composition, comprising, a thermotropic liquid crystalline polymer coated with a metal layer of palladium and optionally one or more other metals; wherein said metal layer has a total thickness of about 5 μm or more, said palladium is in contact with said liquid crystalline polymer, and an adhesive peel strength of said metal layer to said liquid crystalline polymer of at least about 0.1 N/mm when measured according to DIN Method 53494.

### DESCRIPTION OF THE INVENTION

Liquid Crystalline Polymers (LCPs)

Thermotropic liquid crystalline polymers (LCPs) are known in the art by various terms, including “liquid crystal” and “anisotropic melts.” A polymer is optically anisotropic if, in the melt phase, it transmits light when examined between crossed polarizers using a polarizing microscope. By “thermotropic” is meant that the polymer may be melted and then re-solidified, i.e. is thermoplastic. Any thermotropic LCP may be used in this process.

Useful thermotropic LCPs include polyesters, poly(ester-amides), poly(ester-imides), poly(ester-amide-imides), polyazomethines, or mixtures thereof. These terms have their usual meaning, and simply indicate that the repeat units in the polymer are joined by ester and optionally amide and/or imide linkages. Preferred thermotropic LCPs are polyesters or poly(ester-amides), and it is especially preferred that the polyester or poly(ester-amide) is partly or fully aromatic. By “aromatic” is meant that, except for the carbon atoms contained in functional groups such as ester, amide or imide, all of the carbon atoms in the main chain of the polymer are present in aromatic rings such as phenylene, naphthylylene, biphenylene, etc. Carbon atoms in other types of groupings such as alkyl may be present as substituents on the aromatic rings, as in a repeat unit derived from methylhydroquinone or 2-t-butyl-4-hydroxybenzoic acid, and/or also present at other places in the polymer such as in n-alkyl amides. Other substituent groups such as halogen, ether, and aryl may also be present in the LCP.

As the components of the polyesters used in the preferred LCP compositions of the present invention, there may be used for example: i) hydroquinone; ii) 4,4′-dihydroxybiphenyl (4, 4′-biphenol); iii) isopthalic acid; iv) terephthalic acid; v) p-hydroxybenzoic acid or its derivatives; vi) 4,4′-dihydroxybiphenyl (4,4′-bibenzoic acid) or its derivatives; viii) 2,6-naphthalenedicarboxylic acid; iv) 6-hydroxy-2-naphthoic acid, or combinations thereof. These components are all known in the art and are commercially available or can be prepared by techniques readily available to those in the art.

Included within the definition of LCP are those LCPs which contain the usual types of material mixed into such polymers, such as reinforcing agents, fillers, pigments, antioxidants, etc. Examples of such materials include glass fiber, milled glass fiber, minerals such as mica and clays, titanium dioxide, carbon fiber, aramid fiber, and talc.

Sputtering and Ion-Plating LCPs with Palladium

Sputtering and ion-plating are well-known methods of coating substrates with metals and other types of materials. Basically in both processes, the metal is vaporized and converted partially or completely to an ion during or after the vaporization, and the metal ions are drawn to the substrate (the item to be metal coated) by an electric field. The metal is vaporized by bombardment with energetic ions (sputtering) or by evaporation (ion-plating). Improved adhesion over simple vacuum evaporation deposition is often achieved because, it is believed, the metal atoms are propelled into the substrate surface by electrostatic forces.

It has been found that when palladium is sputtered or ion-plated onto an LCP, the palladium layer formed adheres well to the LCP, and just as importantly forms a good interlayer for the further coating, as by electroplating, of metals. This is important, since sputtering or ion-plating itself usually is more useful for making very thin coatings, usually <3 μm, more often ≦1 μm. Thicker coatings are often needed, for example to reduce the electrical resistance of the coating.

Before sputtering or ion-plating, or for that matter before most metal coating techniques are used, the surface of the substrate, in this case the LCP, should preferably be clean. It should be particularly free of greases in any form, such as fingerprints or mold release. The surfaces of the LCP may be cleaned by normal methods, for instance exposure to aqueous cleaning agents such as detergents, and/or immersion in organic solvents such as acetone or ethanol. Of course any residues from the cleaning solutions, such as detergents should be rinsed away by an appropriate solvent such as water. When immersed in a liquid cleaning agent the cleaning process may be accelerated by use of ultrasonic energy, and the use of an aqueous cleaning agent combined with treatment by ultrasonic energy is a preferred cleaning method.

It is preferred, but not necessary, that the LCP substrate be dried at elevated temperature before being placed into the sputtering or ion-plating chamber and a vacuum applied (to either coat the Pd or plasma etch first, see below). It is believed this pre-drying shortens the time in the chamber needed to remove the gases dissolved in the LCP. Drying is preferably accomplished by heating the LCP at from about 120° C. to about 220° C., or the melting point of the LCP or the glass transition point of the LCP if is amorphous, whichever is lower, for about 1 hour to about 24 hours. Longer heating times may be used, but generally do not improve the results substantially.

Preferably, the surface should also be roughened and/or chemically modified before sputtering of the palladium (Pd) begins. In ion-plating, it is believed that the surface of the substrate is etched simultaneously with the metal plating. A preferred method of roughening is by plasma etching, which may be achieved in the sputtering chamber before the Pd is sputtered. The plasma etching may be done with any number of gases, for instance inert gases such as argon, or other gases such as nitrogen or oxygen, or any mixture of these. Preferred gases for etching are argon, oxygen, a mixture of argon and oxygen or nitrogen, and oxygen. A mixture of oxygen and argon is particularly preferred. The length of time of plasma etching will be somewhat dependent on the power level used, the substrate, and other factors, but is typically in the range of about 2 to 60 min.

Roughening of the surface may also be accomplished by other means. Chemical etching by solutions may be employed, see for instance European Patent 214,827 B 1, which is hereby included by reference. In this method, an etching solution of uniform composition comprising an acid, an alcohol, or an alkali and a metal layer is applied to the etched surface by sputtering, plating, or vacuum deposition. Alternatively, the surface may simply be mechanically roughened, see for instance U.S. Pat. No. 5,085,015, which is hereby included by reference. In this method, the surface is roughened by subjecting it to abrasion, preferably by a stream of abrasive particles. Those particles may be propelled by any suitable fluid, but most commonly will be air-propelled. It is also possible that the surface may be “pre-roughened” during the forming of the LCP piece, by for example, using a mold with a surface which is itself relatively rough.

The sputtering or ion-plating conditions used to coat the LCP are those that are typically used in these processes, especially when palladium is the metal being coated. For instance (see the Examples below in Table 1 for more details) in the apparatus used herein, using a single Pd target, 60 volts on the anode, a coating power of 500 watts, and high frequency power of 30 watts, Pd layers with various thicknesses were generated, depending on coating time.

TABLE 1

| Coating | Pd Thickness, |
|---|---|
| Time, sec. | μm |
| 2000 | 1 |
| 310 | 0.2 |
| 125 | <0.1 |

It is preferred that the maximum thickness of the Pd coating is about 3 μm, and more preferably about 0.05 μm to about 1 μm. The Pd coating thickness may be measured by any of a number of standard methods using equipment such as a Fischerscope® X-Ray System XUVM, sold by Helmut Fischer Gmbh, Singelfingen, Germany.

The maximum temperature of the substrate LCD in the process should not exceed the melting point of the LCP or the glass transition point of the LCP if is amorphous, and should preferably be at least 50° C. below the melting point or glass transition point (if amorphous). Melting point and glass transition point are measured by Differential Scanning Calorimetry according to ASTM method D3418. Typically, the temperature of the LCP during the Pd coating process will be about 60° C. to about 250° C., but this will depend on the power used during the coating process, the amount of cooling applied to the LCP substrate, the thickness of the substrate if any, and other factors.

The Pd layers as produced by sputtering or ion-plating generally have adhesion to the LCP substrate of at least 2 MPa, preferably about 10 MPa or more, and most preferably about 20 MPa or more when measured by the method of DIN EN 582.

Once the Pd has formed a layer on the LCP, it may be used as is. For example, the Pd coated LCP may be used for electromagnetic shielding for computers or other electronic devices. It may be etched to form a metallic Pd pattern on the surface of the LCP. For example, a resist such as a photoresist may be used to form a pattern on the Pd surface, the uncoated Pd chemically etched away, and then the remaining resist removed leaving a patterned Pd layer, which may be used as a circuit board.

Electrolytically Plating with Other Metals

However, for many uses, the Pd layer remaining whether patterned or not may not be useful because it is too thin. This may cause the layer to be easily mechanically removed, as by abrasion, or it may have too high an electrical resistance, i.e., it can't carry enough electrical current. In this case, it is desirable to increase the thickness of the metal layer on the LCP without lowering the adhesion of the metal layer to the LCP to the point where it can be easily detached from the LCP. This is particularly critical if in its final form, the metal layer is to be at least partially in the form of one or more thin strips. Some particularly useful metals to be electrolytically plated are those that have relatively low electrical resistances, such as copper and silver.

It has been surprisingly found that Pd layers can be electrolytically plated by a metal such as copper to increase the total thickness of the metal layer many fold without adversely affecting the adhesion of the metal layer to the LCP. The electrolytic plating may be carried out using standard materials and methods of electroplating metals which are well known in the art as described in textbooks, see for instance B. Gaida, et al., Technologie der Galvanotechnik, Eugen G. Leuze Verlag, Saulgau, Germany, 1996 and N. V. Parthasaradhy, Practical Electroplating Handbook, Prentice Hall, Englewood Cliffs, N.J., 1989.

It has also been surprisingly found that when the Pd layer is electrolytically metal plated, exceptionally high current densities may be used as opposed to other metal coatings on LCPs such as copper. When a copper layer is sputtered onto an LCP, it may be electrolytically plated with copper at a current density of up to about 3 A/dm². Much higher current densities, such as 5 A/dm², result in very poor quality metal plating having blisters and more importantly, spontaneous delamination of the metal coating from the LCP surface coated with copper. However, if the original metal layer is Pd, high current densities such as 18 A/dm² may be used and thus allowing additional metal coatings such as copper to be obtained. This higher current density in the electrolytic plating means that metal thickness in the plated layer may be built up much faster. For instance at 5 A/dm², the buildup in a particular copper plating was 1 μm/min. While at the higher 10 A/dm², the buildup rate of copper was 2.5 μm/min. It is preferred that the buildup, or plating rate (increase in thickness) is about 2.5 μm/min or more, more preferably about 4 μm/min or more. It is preferred that the total thickness of the metal layer on the LCP (palladium plus any other metals) is finally about 5 μm to about 100 μm.

The Pd layer or LCP itself may be treated in other ways before electrolytically metal plating the Pd layer. For example, the Pd layer and/or LCP surface may be roughened, and/or the Pd layer and/or LCP surface may be treated briefly with an electroless metal plating solution.

No matter what current density metal is electrolytically plated on the Pd layer which is coated on the LCP, the resulting metal coating [Pd plus the other metal(s)] usually has very good adhesion to the LCP. Adhesion of this type of metal layer is measured by DIN Method 53494 (identical to International Electronic Commission Method 326, part 2), which is a peel type of adhesion, and reported in units of N/mm. It is preferred that this adhesion is about 0.1 N/mm or more, more preferably about 0.2 N/mm, and especially preferably about 0.3 N/mm or more.

Preferred metals to be electrolytically plated are copper, silver, palladium, gold, chromium, nickel and tin. Copper is especially preferred.

Whether electrolytically plated with additional metal or not, when patterned, the Pd coated LCPs described above can serve as printed circuit boards or printed wiring boards.

### EXAMPLES

In the Examples, the following procedures, measurement methods, and materials were used.

Metal Layer Thickness—This was measured using a Fischerscope® X-Ray System XUVM, sold by Helmut Fischer GmbH, Singelfingen, Germany. The measurement is made by well-known quantitative methods, such as described in J. M. Girffiths et al., X-Ray Spectrometry (New York), Vol. 61, p. 5 et seq. (I986), and R. Tertian, et al., Principles of Quantitative X-Ray Fluorescence Analysis, Heyden, London (1982).

Adhesion of Pd Layers (<3 μm thick)—Adhesion of these layers was measured by the method of DIN EN 582.

Adhesion of Metal Layers (≧5μm thick)—Adhesion of this type of metal layer was measured by DIN Method 53494 (identical to International Electronic Commission Method 326, part 2).

LCPs Used

All of the LCP grades used contained the same LCP (except for Type B), with the filler and molding conditions being varied. The LCP was, except for type B, was the same as described in U.S. Pat. No. 5,110,896, Tables I and II, and called “LCP 9”. The polymer for Type was the same except the ratio of terephthalic acid/2,6-naphthalene dicarboxylic acid (T/2,6-N) was 87.5/12.5 All filler amounts are percent by weight.

Type A—This contained 40% TiO₂ and 60% polymer. It was molded using 350° C. injection molding barrel temperatures and a slow injection speed.

Type B—This contained 40% talc, 5% TiO₂ and 55% polymer. It was molded using 350° C. injection molding barrel temperatures and a normal injection speed.

Type C—This contains 30% talc and 70% polymer. It was molded using 350° C. injection molding barrel temperatures and a fast injection speed, with the mold at 100° C.

Type D—This contains 25% TiO₂, 15% talc, 10% glass fiber and 50% polymer. It was molded using 350° C. injection molding barrel temperatures and a 145° C. mold temperature.

Type E—This contains 50% glass fiber and 50% polymer. It was molded using 350° C. injection molding barrel temperatures with a 145° C. mold.

Type F—The same as Type E except the mold temperature was 95° C.

Roughness—Surface roughness, R_{z}, was measured by the method described in DIN 4768, using a diamond stylus. Surface roughnesses on as molded plaques before treatment are given in Table 2.

TABLE 2

| | Surface |
|---|---|
| | Roughness |
| LCP Type | R₂, μm |
| A | 1.15 |
| B | 2.24 |
| C | 2.96 |
| D | 3.27 |
| E | 5.75 |
| F | 7.85 |

### Examples 1-12

Flat plaques of the appropriate LCPs were injection molded using standard injection molding techniques, including temperature in the injection molding machine appropriate to the particular LCP used (see the original references listed above). The plaque mold temperature is noted above in the listing of LCPs.

Plasma Etching and Sputtering of Pd—All of the LCP samples were plaques of the approximate dimensions 6×7.5×1.6 mm. They were initially cleaned in an aqueous cleaning, Delothen® NK1, obtained from DELO Gmbh & Co., Postfach 1231, 86882 Landsberg, Germany. After rinsing away residual detergent with distilled water, the plaques were dried in an air oven at 60° C. for at least 2 h, or at higher temperatures for a period of time (noted in the Tables 5 below).

After drying, the plaques were placed in a sputtering apparatus, Model No.

CC800 made by CemeCon GmbH, Talbotstr. 21, 52068 Aachen, Germany. This apparatus was equipped with a turntable on which the LCP substrate was mounted. A single Pd target was used. Conditions for the etching (if done) and subsequent sputtering are given in Tables 2 and 3, respectively. During etching the pressure in the chamber was about 150 mPa. During sputtering the pressure was generally about 700 mPa. If an Ar/O₂ mixture was used for the etching, the molar ratio of Ar:O₂ was about 1:1. After the sputtering was complete, the plaques were generally allowed to cool in the vacuum chamber. Sometimes the rate of Ar flow was increased to speed the cooling.

Table 3 also give results of the sputtering, such as Pd layer thickness formed and adhesion of the Pd layer. The temperatures given are the maximum temperatures reached during the etching (if done) and sputtering.

TABLE 3^{a}

| | | Pd | | | | | HF | | Adhesion |
|---|---|---|---|---|---|---|---|---|---|
| Ex. | LCP | Thickness | Etching | Etching | Etching | Coating | Power^{b} | Temp | of |
| No. | Type | Attained, μM | Gas | Power (W) | Time (s) | Time (s) | (W) | (° C.) | Pd (MPa) |
| 1a | A | 1 | No etching | | | 2000 | 30 | 70 | <0.6 |
| 1b | B | 1 | No etching | | | 2000 | 30 | 70 | 10.4 |
| 1c | C | 1 | No etching | | | 2000 | 30 | 70 | 5.1 |
| 1d | D | 1 | No etching | | | 2000 | 30 | 70 | 13.4 |
| 1e | E | 1 | No etching | | | 2000 | 30 | 70 | 15.1 |
| 1f | F | 1 | No etching | | | 2000 | 30 | 70 | 16.0 |
| 2a | A | 1 | No etching | | | 2000 | 0 | 60 | <0.6 |
| 2b | B | 1 | No etching | | | 2000 | 0 | 60 | 8.4 |
| 2c | C | 1 | No etching | | | 2000 | 0 | 60 | 6.0 |
| 2d | D | 1 | No etching | | | 2000 | 0 | 60 | 14.0 |
| 2e | E | 1 | No etching | | | 2000 | 0 | 60 | 20.5 |
| 2f | F | 1 | No etching | | | 2000 | 0 | 60 | 18.4 |
| 3a | A | 1 | Ar/O₂ | 600 | 600 | 2000 | 30 | 77 | 2.8 |
| 3b | B | 1 | Ar/O₂ | 600 | 600 | 2000 | 30 | 77 | 7.3 |
| 3c | C | 1 | Ar/O₂ | 600 | 600 | 2000 | 30 | 77 | 13.2 |
| 3d | D | 1 | Ar/O₂ | 600 | 600 | 2000 | 30 | 77 | 12.4 |
| 3e | E | 1 | Ar/O₂ | 600 | 600 | 2000 | 30 | 77 | 20.1 |
| 3f | F | 1 | Ar/O₂ | 600 | 600 | 2000 | 30 | 77 | 26.0 |
| 4a | A | 1 | Ar/O₂ | 600 | 300 | 2000 | 30 | 70 | 1.3 |
| 4b | B | 1 | Ar/O₂ | 600 | 300 | 2000 | 30 | 70 | 8.9 |
| 4c | C | 1 | Ar/O₂ | 600 | 300 | 2000 | 30 | 70 | 5.3 |
| 4d | D | 1 | Ar/O₂ | 600 | 300 | 2000 | 30 | 70 | 13.2 |
| 4e | E | 1 | Ar/O₂ | 600 | 300 | 2000 | 30 | 70 | 26.8 |
| 4f | F | 1 | Ar/O₂ | 600 | 300 | 2000 | 30 | 70 | 27.1 |
| 5a | A | 1 | Ar/O₂ | 300 | 300 | 2000 | 30 | 59 | 1.3 |
| 5b | B | 1 | Ar/O₂ | 300 | 300 | 2000 | 30 | 59 | 9.2 |
| 5c | C | 1 | Ar/O₂ | 300 | 300 | 2000 | 30 | 59 | 7.1 |
| 5d | D | 1 | Ar/O₂ | 300 | 300 | 2000 | 30 | 59 | 7.9 |
| 5e | E | 1 | Ar/O₂ | 300 | 300 | 2000 | 30 | 59 | 12.4 |
| 5f | F | 1 | Ar/O₂ | 300 | 300 | 2000 | 30 | 59 | 15.0 |
| 6a | A | 1 | O₂ | 600 | 600 | 2000 | 30 | 75 | 0.9 |
| 6b | B | 1 | O₂ | 600 | 600 | 2000 | 30 | 75 | 9.8 |
| 6c | C | 1 | O₂ | 600 | 600 | 2000 | 30 | 75 | 8.6 |
| 6d | D | 1 | O₂ | 600 | 600 | 2000 | 30 | 75 | 14.8 |
| 6e | E | 1 | O₂ | 600 | 600 | 2000 | 30 | 75 | 13.2 |
| 6f | F | 1 | O₂ | 600 | 600 | 2000 | 30 | 75 | 25.6 |
| 7a | A | 1 | O₂ | 600 | 300 | 2000 | 30 | 61 | 6.6 |
| 7b | B | 1 | O₂ | 600 | 300 | 2000 | 30 | 61 | 3.7 |
| 7c | C | 1 | O₂ | 600 | 300 | 2000 | 30 | 61 | 9.7 |
| 7d | D | 1 | O₂ | 600 | 300 | 2000 | 30 | 61 | 10.9 |
| 7e | E | 1 | O₂ | 600 | 300 | 2000 | 30 | 61 | 12.8 |
| 7f | F | 1 | O₂ | 600 | 300 | 2000 | 30 | 61 | 21.2 |
| 8a | A | 1 | O₂ | 300 | 300 | 2000 | 30 | 60 | 4.3 |
| 8b | B | 1 | O₂ | 300 | 300 | 2000 | 30 | 60 | 1.2 |
| 8c | C | 1 | O₂ | 300 | 300 | 2000 | 30 | 60 | 10.4 |
| 8d | D | 1 | O₂ | 300 | 300 | 2000 | 30 | 60 | 13.4 |
| 8e | E | 1 | O₂ | 300 | 300 | 2000 | 30 | 60 | 9.7 |
| 8f | F | 1 | O₂ | 300 | 300 | 2000 | 30 | 60 | 16.0 |
| 9a | A | 0.2 | Ar/O₂ | 600 | 1200 | 310 | 30 | 75 | — |
| 9b | F | 0.2 | Ar/O₂ | 600 | 1200 | 310 | 30 | 75 | — |
| 10a | A | <0.1 | Ar/O₂ | 600 | 600 | 125 | 0 | 56 | — |
| 10b | F | <0.1 | Ar/O₂ | 600 | 600 | 125 | 0 | 56 | — |
| 11a | A | <0.1 | Ar/O₂ | 600 | 1200 | 125 | 0 | 76 | — |
| 11b | F | <0.1 | Ar/O₂ | 600 | 1200 | 125 | 0 | 76 | — |
| 12a | A | <0.1 | Ar/O₂ | 600 | 2400 | 125 | 0 | 102 | — |
| 12b | F | <0.1 | Ar/O₂ | 600 | 2400 | 125 | 0 | 102 | — |

^{a}For all Examples, coating (sputtering) power was 500 W for one target, and the anode voltage was 60 V.
^{b}The HF power is high frequency power during sputtering.

### Examples 13-28

Electrolytic Deposition of Copper on Palladium Layers on LCP—Some of the Pd coated plaques made in Examples 1-12 were electrolytically coated with copper.

The electrolytic plating was carried out in an apparatus that had two copper anodes. The plaques to be plated were part of the cathode equidistant between the anodes. This distance from the cathode to each anode was about 5 cm.

Two types of commercially purchased electrolytes were used. The first of these was Cupracid® 828 obtained from Atotech Gmbh, Erasmussstrasse 20, D10553 Berlin, Germany, and was used when the current density was 10 A/dm². The second electrolyte was MACuPlex® J-64 purchased from MacDermid, Inc. Waterbury, Conn. 06702, U.S.A. and was used whenever the current density was 18 A/dm².

The electrolysis was carried out as a constant current operation, with the voltage being controlled to maintain a constant current. Electrolyses in which the current density was 10 A/dm² were run about 10 min, and when the current density was 18 A/dm² the electrolysis was run for about 7 min.

All of the samples had a smooth copper coating that usually appeared somewhat shiny. Peel adhesion was measured before and after heat aging in air using the method of DIN 53494. Virtually all of the failures in the peel adhesion test were cohesive failures of the LCP.

TABLE 4^{a}

| | Pd Coated | | Current | Peel | Peel |
|---|---|---|---|---|---|
| | Plaque from | | Density | Adhesion^{b} | Adhesion^{c} |
| Ex. No. | Ex. No. | LCP Type | A/dm² | N/mm | N/mm |
| 13 | 9b | F | 10 | 0.42 | 0.50 |
| 14 | 9b | F | 18 | 0.32 | 0.53 |
| 15 | 10b | F | 10 | 0.16 | 0.50 |
| 16 | 10b | F | 18 | 0.23 | 0.59 |
| 17 | 11b | F | 10 | 0.33 | 0.41 |
| 18 | 11b | F | 18 | 0.41 | 0.06 |
| 19 | 12b | F | 10 | 0.51 | 0.48 |
| 20 | 12b | F | 18 | 0.49 | 1.00 |
| 21 | 9a | A | 10 | 0.04 | 0.15 |
| 22 | 9a | A | 18 | 0.11 | 0.17 |
| 23 | 10a | A | 10 | 0.08 | 0.15 |
| 24 | 10a | A | 18 | 0.02 | 0.10 |
| 25 | 11a | A | 10 | 0.04 | 0.10 |
| 26 | 11a | A | 18 | 0.16 | 0.13 |
| 27 | 12a | A | 10 | 0.03 | 0.03 |
| 28 | 12a | A | 18 | 0.01 | 0.01 |

^{a}Final thickness of the Cu layer in all cases was 25 μm.
^{b}Measured directly after electrolytically plating.
^{c}Measured after electrolytically plating and heat aging 96 h at 150° C.

What is claimed is:

1. A process for coating a thermotropic liquid crystalline polymer with palladium, comprising, coating a surface of said liquid crystalline polymer with palladium by sputtering or ion-plating.

2. The process as recited in claim 1 wherein coating said surface is by sputtering.

3. The process as recited in claim 2 wherein said surface is roughened before said coating.

4. The process as recited in claim 1 wherein a palladium layer having a thickness of about 3 μm or less is produced.

5. The process as recited in claim 1 wherein said palladium layer has an adhesion to said liquid crystalline polymer of about 2 MPa or more when measured by DIN Method EN 582.

6. The process as recited in claim 1 wherein:
said liquid crystalline polymer is cleaned before said coating; then
said liquid crystalline polymer is dried before said coating by heating;
said liquid crystalline polymer is roughened in a sputtering chamber by plasma etching; and
said liquid crystal polymer is coated with palladium.

7. The product of the process of claim 1

8. The process as recited in claim 1 wherein said liquid crystalline polymer is a polyester or a poly(ester-amide).

9. A composition, comprising, a thermotropic liquid crystalline polymer coated with palladium, wherein said palladium has a thickness of less than about 3 μm, and has an adhesive strength to said liquid crystalline polymer of at least about 2 MPa when measured according to the method of DIN EN 582.

10. An article of the composition of claim 9.

11. A process for making a metal coated liquid crystalline polymer composition, comprising, electrolytically metal plating an liquid crystalline polymer having a palladium surface layer less than about 3 μm thick, and provided that:
said metal plating takes place on a surface of said palladium layer;
a current density during said metal plating is at least about 5 A/dm² of an area of said surface of said palladium layer, or said metal plating takes place at a rate of at least 1 μm/min, or both.

12. The process as recited in claim 11 wherein copper, silver, gold, chromium, nickel, tin or palladium is electrolytically plated.

13. The process as recited in claim 12 wherein copper is electrolytically plated.

14. The product of the process as recited in claim 11.

15. The process as recited in claim 11 wherein a metal layer formed has a peel adhesion to said liquid crystalline polymer of at least 0.1 N/mm when measured according to DIN Method 53494.

16. A process for making a metal coated liquid crystalline polymer composition, comprising, electrolytically metal plating an liquid crystalline polymer having a palladium surface layer less than about 3 μm thick, provided that said electrolytic metal plating takes place on a surface of said palladium layer.

17. The process as recited in claim 16 wherein copper, silver, gold, chromium, nickel, tin or palladium is electrolytically plated.

18. The process as recited in claim 16 wherein said palladium layer is about 0.05 μm to about 1.0 μm thick.

19. A composition, comprising, a thermotropic liquid crystalline polymer coated with a metal layer of palladium and optionally one or more other metals, wherein:
said metal layer has a total thickness of about 5 μm or more;
said palladium is in contact with said liquid crystalline polymer; and
an adhesive peel strength of said metal layer to said liquid crystalline polymer of at least about 0.1 N/mm when measured according to DIN Method 53494.

20. An article of the composition of claim 19.
